(19) United States
(12) Patent Application Publication
(10) Pub. No.: US 2005/0226298 A1
(43) Pub. Date: Oct. 13, 2005

(54) Power conversion device

(75) Inventor: Takamasa Asai, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: MITSUBISHI DENKI KABUSHIKI KAISHA

(21) Appl. No.: 11/097,253

(22) Filed: Apr. 4, 2005

(30) Foreign Application Priority Data
Apr. 8, 2004 (JP) JP2004-114652

(51) Int. Cl. H01S 5/00

(52) U.S. Cl. 372/50.1

(57) ABSTRACT

A large amount of heat generation is incidental to conventional power conversion devices due to large ion voltage of a diode element rectifying AC power to DC power. Moreover, in the heat generation, power generation operation has to be stopped to prevent burnout of the diode element, resulting in restriction on power conversion functions. In the power generation mode that diode elements 4 rectifies an AC power generated by a generator-motor 6, a diode element being in conduction state is detected out of the diode elements 4 in accordance with an output signal from a current sensor mounted on an AC power line of the generator-motor 6, and a switching element 3 that is connected in parallel with the diode element 4 is turned ON. Most of current of the diode element 4 flow through the switching element 3, resulting in reduction of heat generation of the diode element 4.

### BACKGROUND OF THE INVENTION

1. Field of the Invention

The present invention relates to an improvement of a power conversion device to be inserted between a DC power supply and an AC generator-motor.

2. Description of the Related Art

In a hybrid electric vehicle, a power conversion device is used. This power conversion device serves to convert a DC electric power of a DC power supply such as battery into an AC power having an arbitrary frequency to drive an AC motor, and to rectify an AC power having been generated to charge the mentioned DC power supply when the AC motor operates as a generator (for example, at the time of regenerative braking).

A power conversion device, for example, as disclosed in FIG. 2 of the Japanese Patent Publication (unexamined) No. 191691/1998 includes an inverter module 10 that is arranged of a plurality of switching elements 8 and a plurality of diode elements 9, and AC/DC conversion operation is performed with this arrangement. As this power conversion operation goes on, current flows through the switching elements 8 and the diode elements 9, and these switching elements and diode elements come to generate heat. In the power conversion device arranged as shown in FIG. 2 of the Japanese Patent Publication (unexamined) No. 191691/1998, the rectification with the diode elements 9 is carried out when AC is converted to DC in the process of power generation operation, and the diodes 9 generates heat. It is a matter of course that current also flows through the switching elements 8 and the switching elements generate heat in some operation modes.

In this respect, a voltage across terminals (voltage between anode/cathode, being generally around 0.7V) of a diode element 9 when current flows is larger than that of a switching element 8 (in the case of a MOS-type transistor of several mΩ of ON resistance, it is around several hundreds mV even if 100A flows); so that the diode element 9 generates a larger amount of heat than the switching element 8 does even when the same amount of current flows through both of them.

Furthermore, for example, in the case of a high ambient temperature, a diode element is brought in the overheat state at the time of operation of generating a large electric power. Therefore, supposing that no restriction of current flow is made, a temperature of the diode element exceeds an allowable temperature range, and eventually there will be some cases where a power conversion device is out of order. To meet this disadvantage, according to the mentioned Japanese Patent Publication. (unexamined) No. 191691/1998, an overheat state of the diode element 9 is detected with a thermistor 21. That is, in the case where any overheat state is determined, the power generation operation is suppressed. When the overheat state is not improved even if a predetermined time period has passed after the suppression, the power generation operation is stopped, thereby carrying out protection from the overheat of a power conversion device.

However, since the overheat of a diode element 9 is prevented by suppressing or stopping the power generation operation, a problem exists in that functions of a power conversion device are restricted.

In the power conversion device according to the prior art, a large amount of heat is generated since an ON voltage of a diode element is large in order to perform the rectification at the time of power generation operation. Moreover, the power generation operation has to be suppressed or stopped in order to prevent the burnout of a diode element at the time of overheat. Thus, a problem exits in that the operation of generating a large electric power cannot be carried out continuously. In addition, there is a large loss in the power conversion device at the time of power generation operation, resulting in a further problem of low power generation efficiency.

### SUMMARY OF THE INVENTION

The present invention was made to solve the above-mentioned problems and has an object of providing a power conversion device of which functions are less likely to be restricted due to overheat of any diode element by causing the diode element at the time of power generation operation to generate a smaller amount of heat, and which possesses a high power generation efficiency.

To accomplish the foregoing object, a power conversion device according to this invention includes:
diode elements that are respectively connected to a generator driven from outside to generate an AC power, and rectify the mentioned AC power;
switching elements that are connected in parallel with each of the mentioned diode elements;
a current detector that is mounted onto an AC power line providing a connection between the mentioned generator and the mentioned diode elements; and
a synchronous rectifier gate signal generation circuit that detects a diode element being in the conduction state out of the mentioned diode elements in accordance with an output signal from the mentioned current detector, and controls the mentioned switching elements connected in parallel with the mentioned diode element being in the conduction state to cause the mentioned switching element to share a part of current flowing through the mentioned diode element.

In the rectification operation with the diode element at the time of power generation, the switching elements that are connected in parallel are made ON in synchronization with the conduction of the diode element. An ON voltage on the switching elements is lower than that of a diode element, so that current hardly flows through the diode element. As a result, it is possible to reduce a heating level of the entire element.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram showing an arrangement of a power conversion device according to a first preferred embodiment of the present invention.

FIG. 2 is a circuit diagram of a control circuit and a synchronous rectifier gate signal generation circuit of FIG. 1.

FIG. 3 is a waveform chart for explaining operation of the synchronous rectifier gate signal generation circuit of FIG. 2.

FIG. 4 is a circuit diagram showing an arrangement of a power conversion device according to a second embodiment of the invention.

FIG. 5 is a circuit diagram of a control circuit and a synchronous rectifier gate signal generation circuit of FIG. 4.

FIG. 6 is a circuit diagram of a control circuit and a synchronous rectifier gate signal generation circuit according to a third embodiment of the invention.

### DESCRIPTION OF THE PREFERRED EMBODIMENTS

### Embodiment 1

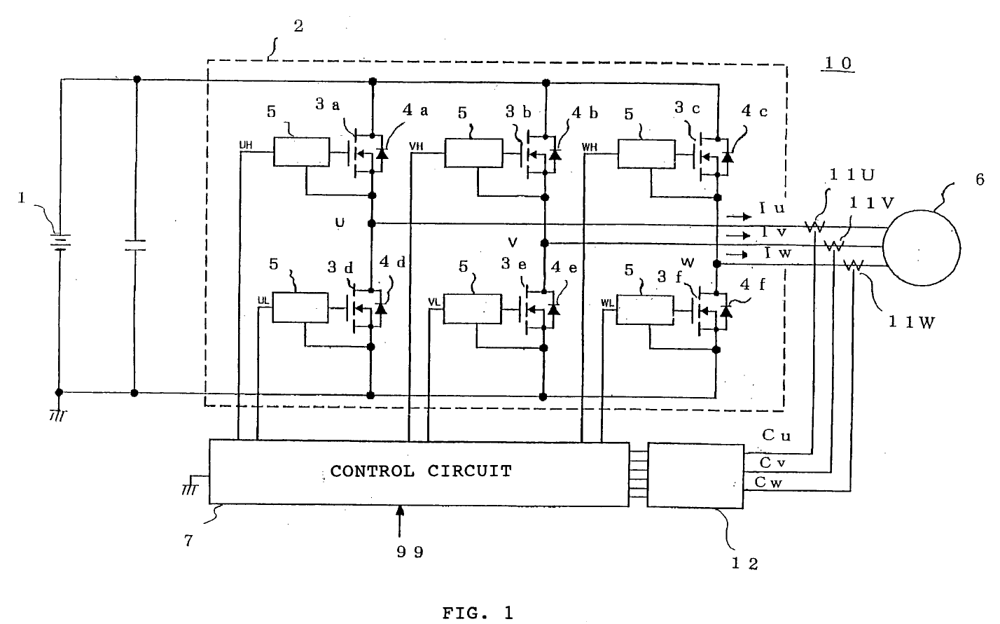

A schematic diagram of the entire arrangement of a power conversion device according to a first preferred embodiment of the present invention is shown in FIG. 1. Positive (+) and negative (−) terminals of a DC power supply 1 are connected to a power conversion section 2 of a power conversion device 10. The power conversion section 2 includes three switching elements 3a, 3b, 3c that are connected to the positive terminal of the DC power supply 1 (for example, a MOS-type transistor having an ON resistance of several mΩ) and three switching elements 3d, 3e, 3f that are likewise connected to the negative terminal of the DC power supply. To these six switching elements 3a, 3b, 3c, 3d, 3e, 3f, diode elements (hereinafter, merely referred to as diodes) 4a, 4b, 4c, 4d, 4e are connected in parallel respectively. For convenience of the description, a part formed of the switching elements 3a, 3b, 3c, 3d, 3e, 3f is hereinafter referred to as a first power conversion section. A part formed of the diodes 4a, 4b, 4c, 4d, 4e, 4f is hereinafter referred to as a second power conversion section.

Each switching element has a control terminal. A gate drive circuit 5 is connected to each of these control terminals. The gate drive circuit 5 possesses functions to insulate a circuit, to shape signals to be inputted into signals of a voltage suitable for the control of the switching element, or to amplify a driving force that controls the switching element.

The switching elements 3a and 3d, the switching elements 3b and 3e, and the switching elements 3c and 3f are connected in series to each other in respective sets. Connection points thereof are outputted to outside of the power conversion section 2 as AC input/output terminals of U phase, V phase, and W phase. An AC generator-motor 6 (hereinafter, referred to as a motor/generator) is connected to the AC input/output terminals U, V, W. In the case of being used in vehicles, generally the motor-generator 6 is a synchronous machine, which rotates in synchronization with an applied AC frequency; and the motor/generator 6 operates as a synchronous generator when an external force drives it. An AC power having been generated is rectified in the second power conversion section to be converted to DC, and fed to regenerate the DC power supply 1.

First, a general operation of the power conversion device 10 of FIG. 1 is described.

When the motor/generator 6 is operated as an electric motor in response to a vehicle control signal 99 to be given from outside (for example, a signal from an accelerator pedal), a control circuit 7 provides signals UH, UL, VH, VL, WH, WL in an appropriate timing via the gate circuits 5 to respective switching elements 3a, 3b, 3c, 3d, 3e, 3f in the first power conversion section, and causes the power conversion section 2 to operate so as to convert a DC voltage of the DC power supply 1 to an AC voltage of an appropriate voltage at an arbitrary frequency. The operation at this time is heretofore known as a general inverter, so that a detailed description is omitted herein. The motor/generator 6 is driven by an AC power having been converted as described above (hereinafter, this operation mode is referred to as power running mode).

Further, when the motor/generator 6 is brought in operation as a generator based on a vehicle control signal 99, an AC power, which the motor/generator 6 generates, is rectified in the power conversion section 2, and fed to regenerate the DC power supply 1.

There are various types of current control at this time mainly in accordance with a rotational speed of the motor/generator 6. For example, current in a field circuit, not shown, is controlled by the control circuit 7 during high-speed rotation, whereby a generated voltage is controlled so that an appropriate charging current can be obtained by a three-phase full-wave rectification with the diodes 4a to 4f of the second power conversion section (hereinafter, this operation mode is referred to as a three-phase full-wave rectification power generation mode).

Further, when an induced voltage of the motor/generator 6 is insufficient to regenerate the DC power supply 1, e.g., during low-speed rotation, the voltage rise is performed by causing the switching elements 3a to 3f to switch, thereby the operation of regenerating the DC power supply 1 being carried out (hereinafter, this operation mode is referred to as an inverter power generation mode).

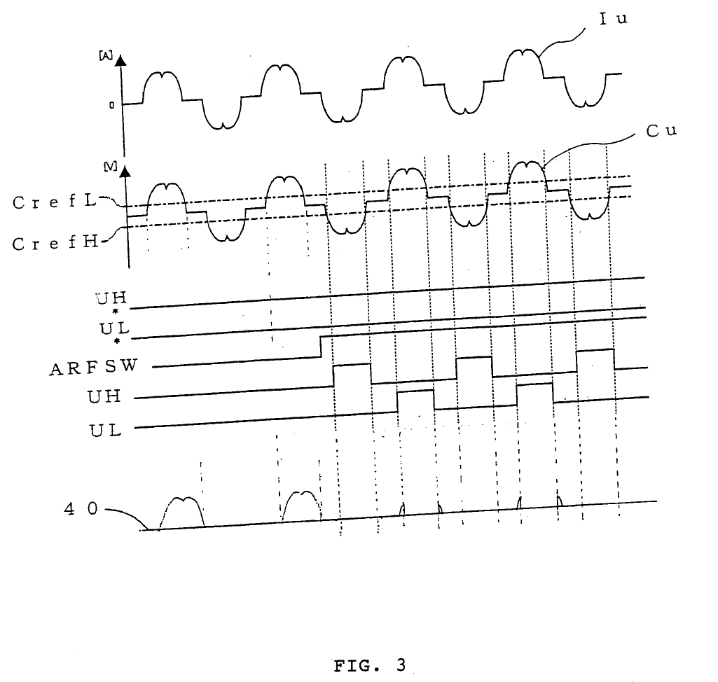

Current sensors 11U, 11V, and 11W are inserted in lines of three phases of the motor/generator 6, and a waveform of an AC current is detected. Iu in FIG. 3 indicates a waveform of the U-phase current. Further, Cu, Cv, and Cw indicate signals that are detected from each phase of current sensors. Cu in FIG. 3 indicates a detected signal of current of U-phase, which is detected from the U-phase of current sensor 11U. Although the signal Cu is a voltage signal herein, a waveform shape thereof is basically the same as Iu. The current sensors 11U, 11V, 11W are capable of detecting amount and direction of currents from waveforms thereof.

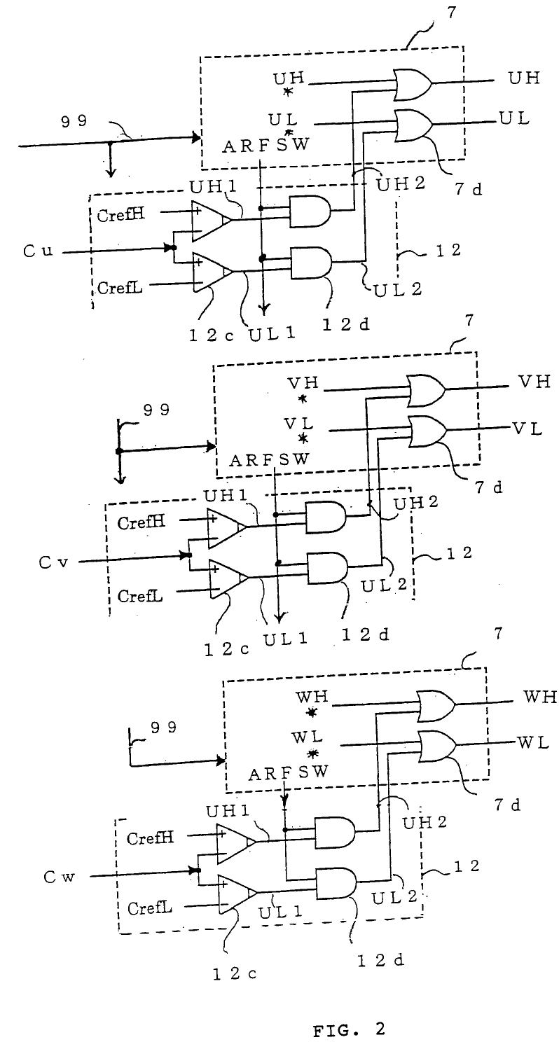

Detected signals of the current sensors 11U, 11V, 11W are inputted to a synchronous rectifier gate signal generation circuit 12. The arrangement of the synchronous rectifier gate signal generation circuit 12 is shown in FIG. 2. Although FIG. 2 shows three phases of circuits, the operation of U phase is hereinafter described.

The synchronous rectifier gate signal generation circuit 12 is provided with a comparator (current comparison circuit) 12c, which compares a detected signal of the current sensor 11U (Cu) having been inputted with a certain level of signal having been preliminarily determined (CrefH and CrefL). When a level of the signal Cu is out of a range that is defined with CrefH or CrefL, specifically, a timing signal UL1 is outputted while a signal Cu exceeds CrefL, or a timing signal UH1 is output while a signal Cu falls below CrefH. The term “a certain level” used herein is, for example, defined as a level at which error determination caused by detection error of the current sensors U, V, W can be prevented. In this manner, it is possible to eliminate, for example, the fluctuation in zero-point output of output signals from a current sensor, or the risk of outputting an erroneous signal of a diode being in conduction although the diode is actually not in any conduction state even in the case where there is output response delay.

Although signals UH1 and UL1 are outputted via an AND gate 12d, a signal of indicating an operation mode (shown with ARFSW in FIG. 2) is inputted to this AND gate 12d from the control circuit 7. This signal ARFSW comes to be H in the three-phase full-wave rectification power generation mode, and comes to be L in the power running mode and the inverter power generation mode. That is, the control circuit 7 outputs operation mode signals indicating the operating state or non-operating state of the first power conversion section and the second power conversion section.

Thus, only in the three-phase full-wave rectification power generation mode and while a value of an AC current exceeds the above-described predetermined level, signals UH2, UL2 are outputted.

Signals UH2, UL2 having been outputted are inserted through an OR gate 7d of the control circuit 7 into an output terminal of signals for the inverter control of the switching elements 3 (indicated with UH*, UL* in the drawing). It is a matter of course that signals UH*, UL* are outputted in the power running mode and the inverter power generation mode, and that signals UH2, UL2 are outputted in the three-phase full-wave rectification power generation mode; and therefore they are not outputted simultaneously, and both signals are not outputted in a duplex manner.

With an output signal UH, the switching element 3a is turned ON in timing of current flowing through the diode 4a. In addition, with a signal UL, the switching element 3d is turned ON in timing of current flowing through the diode 4d. While a voltage between terminals (also referred to as ON voltage) in conduction of a diode (silicon diode) 4 is around 0.7 to 0.8, a switching element 3 (MOS-type transistor) is indicative of only several mΩ in resistance value. Accordingly, most current having been flowing through the diodes come to flow to the switching elements. Therefore, a heating value of the diodes is enormously reduced. This state is shown with a diode current waveform 40 in FIG. 3. Reference numeral 40 indicates such a waveform of current that flows through the diode 4d for the purpose of comparing waveforms before a signal ARFS is inputted and those after a signal ARFS has been inputted. An area of a current waveform after a signal ARFS has been inputted comes to be extremely small. Accordingly, a heating value of a diode becomes ignorably small, and thus a heating value of the entire element depends on a heating value of the switching element.

Explaining this reduction in heat generation, for example, when letting an effective value of current of U phase, a heating value caused by the rectification in the diode 4a is approximately calculated as follows.
Approximately 0.8V×50×( 1/2)=20 W
On the other hand, according to the invention, a heating value at the switching element 3a, in the case where the rectification is performed with a switching element that is connected in parallel with the diode in conduction, is as follows.
Approximately (4 mΩ×50 A)×50 ×(½)=5 W
It will be understood that a heating value thereof becomes drastically smaller. Herein, an ON resistance of a switching element is set to be 4 mΩ. Moreover, when a switching element having a still smaller ON resistance is employed, a higher loss reduction effect can be achieved.

In addition, although the foregoing description is applied to a generator-motor, the power conversion device according to the embodiment is also preferably applied to a rectifier for rectifying outputs from a mere generator with a diode.

As described above, since the switching elements are turned ON in synchronization with the conduction of the rectifier diode at the time of the three-phase full-wave rectification power generation mode, so that a resistance in current paths is decreased. As a result, a heating value of the diode is largely reduced, meanwhile, an increased heating value of the switching elements is very small, thus enabling a heating value of the entire element to decrease, as well as enabling to improve power generation efficiency.

Furthermore, a switch (ARFSW) functioning to make a synchronous rectifier gate signal reactive is provided in a synchronous rectifier gate signal generation circuit so that the generation of gate signals in the operation modes other than the three-phase full-wave rectification power generation mode is not prevented in th0se operation modes. As a result, it is possible to safely carry out the operation without any effect from a synchronous rectifier gate signal generation circuit even at the time of power running mode or the inverter power generation mode.

### Embodiment 2.

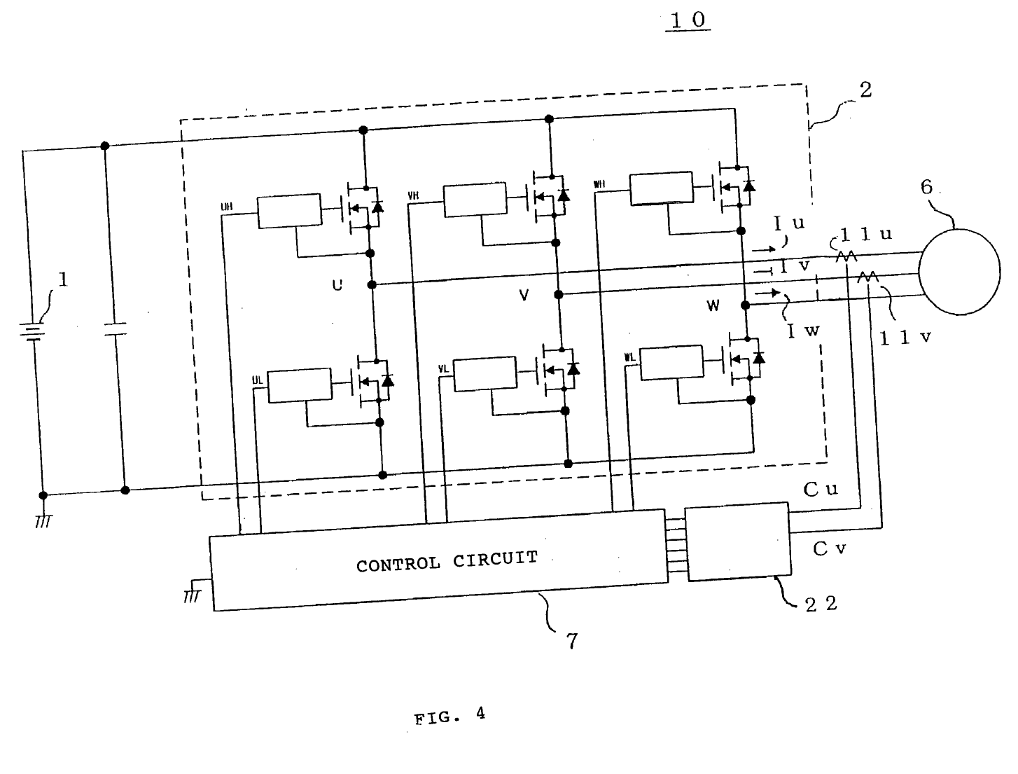

In the foregoing first embodiment, three phases of current sensors 11 are provided as shown in FIG. 1. As shown in FIG. 4, however, on the supposition of mounting only any two phases of current sensors out of U, V and W phases, a current value of the remaining one phase (instantaneous value) can be calculated by simple operation. FIG. 4 shows the entire arrangement of a power conversion device in this sense. Hereinafter, in the drawings, same reference numerals as those in FIGS. 1, 2 and 3 indicate the same or like parts, and detailed descriptions thereof are omitted.

FIG. 4 shows the case where current sensors 11 are mounted on two lines of U phase and V phase to detect currents of these two phases, and a current of W phase is obtained by the operation of currents of these two phases (it is referred to as current operation circuit).

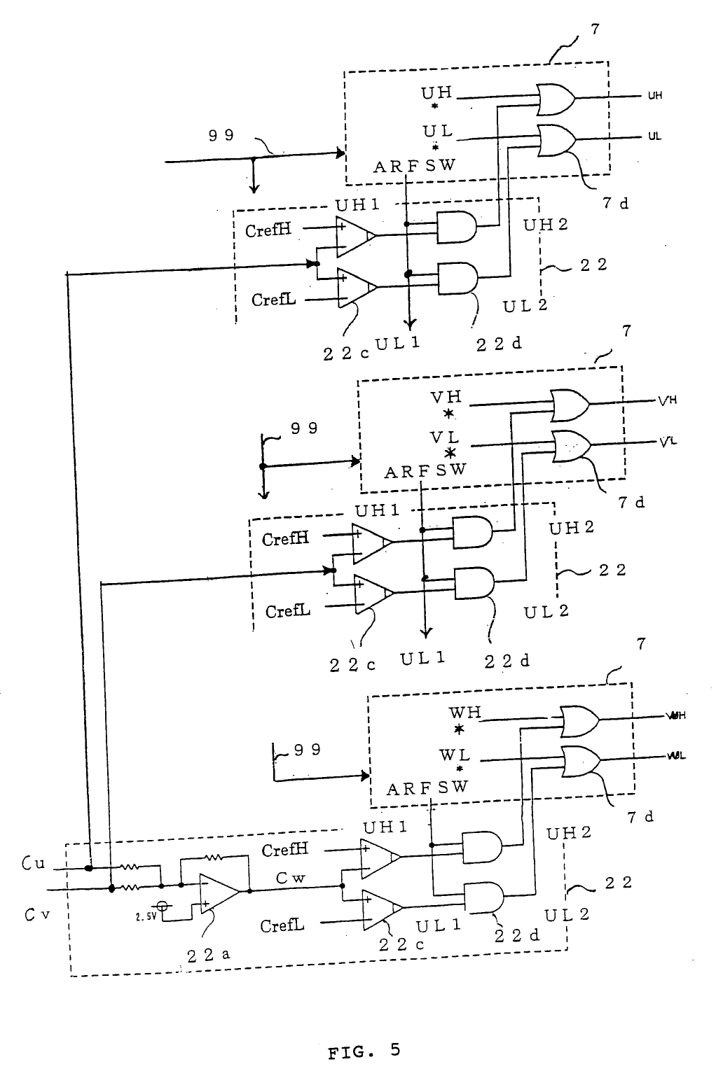

FIG. 5 shows the arrangement of a synchronous rectifier gate signal generation circuit 22 of FIG. 4. The synchronous rectifier gate signal generation circuit 22 adds together and inverts signals Cu and Cv from the current sensors 11 of U phase and V phase in an adding inverting circuit 22a. Simultaneously, when any offset voltage (for example, it is 2.5V in the drawing) is present at the current sensor 11, a difference from this offset voltage is obtained and inverted, thereby generating a dummy current detected signal of W phase. A comparison circuit 22c and an AND gate 22d are the same as the comparison circuit 12c and the AND gate 12d having been described referring to FIG. 2, so that further description thereof is omitted. Diodes being in the conduction state of each phase are detected based on directions of W-phase of current having been obtained and U and V phases of currents having been detected, and gates of the switching elements (MOS-type transistors) 3a to 3f that are connected in parallel with these diodes are brought in ON state.

The other operations are the same as the case of FIGS. 1 and 2 according to the foregoing first embodiment, so that further description thereof is omitted.

### Embodiment 3.

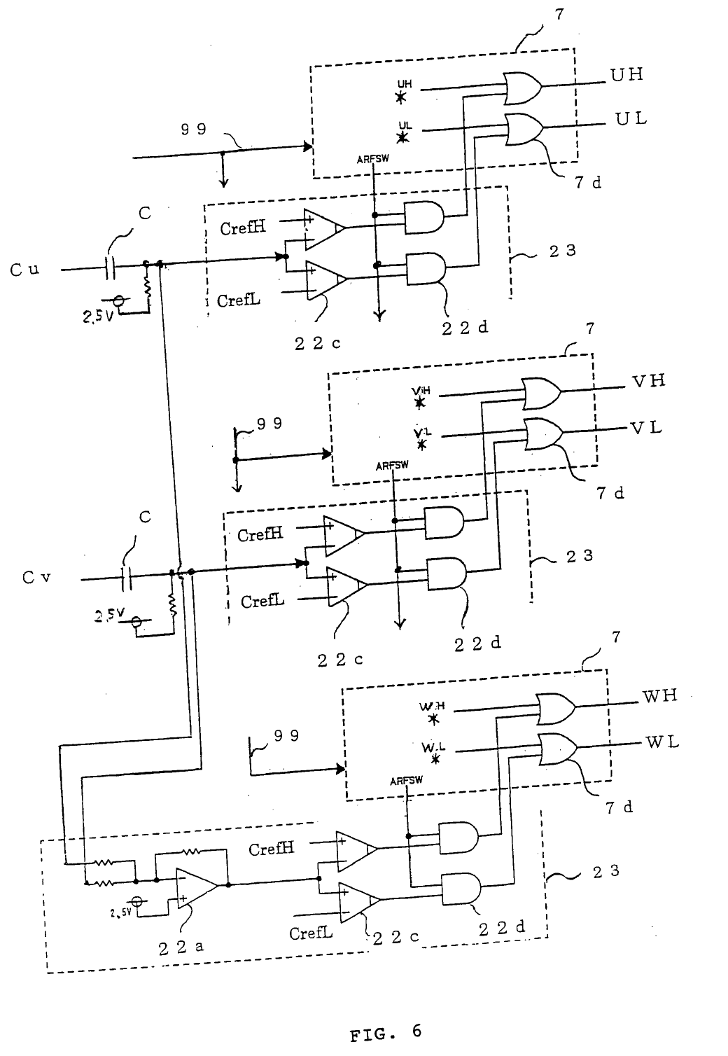

Various types of current sensors 11 are employed for use in vehicles. In some cases where a zero-point voltage output from a current sensor is poor in the aspect of precision (drift of a DC component occurs) as is the case of current sensors employing, for example, a Hall element, ideal output signals from a current sensor can be obtained so as to obtain accurately a direction of phase currents by AC coupling of output signals from the current sensor to interrupt a DC drift component. FIG. 6 shows a synchronous rectifier gate signal generation circuit 23 arranged to perform such an advantage.

FIG. 6 shows an example in which the arrangement according to this third embodiment is applied to the one of FIG. 5 according to the foregoing second embodiment in order to facilitate further understanding. In the drawing, an adding inverting circuit 22a, a comparator 22c, an AND gate 22d and the like are the same as those in FIG. 5, so that further description thereof is omitted.

Reference C designates a capacitor that is inserted in an input line of the comparator 22c to cut a DC level included in an output from the current sensor. A resistor, which is connected between the subsequent stage of the capacitor C and a 2.5V line, acts to cause a zero-point voltage of detected current to be 2.5V, and the invention is not limited to this type or a voltage level.

In such a manner, reference levels CrefH, CrefL of the comparator 22c can be set to be very close to a zero-point output voltage by eliminating the fluctuations in zero-point output from output signals of a current sensor with the use of a capacitor for AC coupling. Accordingly, a period of rectification with switching elements (time length in one cycle) comes to be longer, thus enabling to suppress the heat generation of elements. FIG. 6 shows the case where the capacitor C is added to the embodiment of FIG. 5. The capacitor C can be applied to the one of FIG. 2 according to the foregoing first embodiment as a matter of course.

The power conversion device according to the invention is not limited to a hybrid automobile, but can be applied to an apparatus having a function of generating an AC power and including a diode that rectifies this AC, for example, an AC-driven electric car.

While the presently preferred embodiments of the present invention have been shown and described. It is to be understood that these disclosures are for the purpose of illustration and that various changes and modifications may be made without departing from the scope of the invention as set forth in the appended claims.

1. A power conversion device comprising:
diode elements that are respectively connected to a generator driven from outside to generate an AC power, and rectify said AC power;
switching elements that are connected in parallel with each of said diode elements;
a current detector that is mounted onto an AC power line providing a connection between said generator and said diode elements; and
a synchronous rectifier gate signal generation circuit that detects a diode element being in the conduction state out of said diode elements in accordance with an output signal from said current detector, and controls said switching element connected in parallel with said diode element being in the conduction state to cause said switching element to share a part of current flowing through said diode element.

2. The power conversion device according to claim 1, wherein said generator is an AC generator of three phases, and said current detector detects arbitrary two phases of currents out of three phases.

3. The power conversion device according to claim 2, wherein a current operation circuit is provided to receive a signal of said current detector detecting said two phases of currents and calculate a current waveform of one phase that said current detector has not detected out of said three phases.

4. The power conversion device according to claim 1, wherein an AC coupling circuit is provided to eliminate a zero drift from the output of a signal of said current detector.

5. The conversion device according to claim 1, wherein said synchronous rectifier gate signal generation circuit is provided with a current comparison circuit that outputs a timing signal when a current, which said current detector has detected, exceeds a predetermined level having been preliminarily determined; and
said synchronous rectifier gate signal generation circuit detects a diode element being in the conduction state out of said diode elements with said timing signal, and brings about the operation of controlling said switching element that is connected in parallel with said diode element being in the conduction state.

6. The power conversion device according to claim 1, wherein said synchronous rectifier gate signal generation circuit is provided with a switch that stops the operation of controlling said switching element to cause said switching element to share a part of current flowing through said diode element.

7. The power conversion device according to claim 1, wherein said diode elements are elements arranged in parallel with and parasitic on said switching elements in an internal part of said switching elements.

8. A power conversion device comprising:
a first power conversion section that converts a DC power having been supplied from a DC power supply, to an AC power with a switching element to supply the AC power to a generator-motor;
a second power conversion section that including a diode element that is connected in parallel with said switching element, and converts an AC power, which said generator-motor has generated, to DC to feed the AC power to regenerate said DC power supply;
a control circuit that outputs a control signal to control said switching element, and that outputs an operation mode signal indicating an operating or non-operating state of said first power conversion section, or a non-operating or operating state of said second power conversion section;
a current detector that is mounted onto an AC power line providing a connection between said second power conversion section and said generator-motor; and
a synchronous rectifier gate signal generation circuit that detects a diode element being in the conduction state out of said diode elements in accordance with an output signal from said current detector, and controls said switching element connected in parallel with said diode element in said conduction state to cause said switching element to share a part of current flowing through said diode element when said second power conversion section is determined to operate with said operation mode signal.

9. The power conversion device according to claim 8, wherein said generator-motor is an AC generator-motor of three phases, and said current detector detects arbitrary two phases of currents out of said three phases.

10. The power conversion device according to claim 9, wherein a current operation circuit is provided to receive a signal of said current detector detecting said two phases of currents and calculate a current waveform of one phase said current detector has not detected out of said three phases.

11. The power conversion device according to claim 8, wherein an AC coupling circuit is provided to eliminate a zero drift from the output of a signal of said current detector.

12. The conversion device according to claim 8, wherein said synchronous rectifier gate signal generation circuit is provided with a current comparison circuit that outputs a timing signal when a current, which said current detector has detected, exceeds a predetermined level having been preliminarily determined; and
said synchronous rectifier gate signal generation circuit detects a diode element being in the conduction state out of said diode elements with said timing signal, and brings about the operation of controlling said switching element that is connected in parallel with said diode element being in the conduction state.

13. The power conversion device according to claim 8, wherein said synchronous rectifier gate signal generation circuit is provided with a switch that stops the operation of controlling said switching element to cause said switching element to share a part of current flowing through said diode element.

14. The power conversion device according to claim 8, wherein said diode element is an element arranged in parallel with and parasitic on said switching element in an internal part of said switching element.
